(19) United States
(12) Patent Application Publication
(10) Pub. No.: US 2019/0094595 A1
(43) Pub. Date: Mar. 28, 2019

(54) DISPLAY PANEL AND MANUFACTURING METHOD THEREOF

(71) Applicant: Wuhan China Star Optoelectronics Technology Co., Ltd., Wuhan (CN)

(72) Inventors: Lei XING, Shenzhen (CN); Xi LUO, Shenzhen (CN); Bing GONG, Shenzhen (CN); Xuemin LIU, Shenzhen (CN); Zhonghao DING, Shenzhen (CN)

(21) Appl. No.: 16/058,501

(22) Filed: Aug. 8, 2018

Related U.S. Application Data
(63) Continuation of application No. PCT/CN2018/071466, filed on Jan. 4, 2018.

(30) Foreign Application Priority Data
Sep. 26, 2017 (CN) 201710883544.0

(51) Int. Cl. G02F 1/1339; G02F 1/1362; G02F 1/1343; G02F 1/1335

(52) U.S. Cl. CPC G02F 1/13394; G02F 1/136286; H01L 27/1288; G02F 1/133514; G02F 2201/123; G02F 1/134309

(57) ABSTRACT

The present application provides a display panel, including a first substrate, a liquid crystal layer, a second substrate, and a spacer. The liquid crystal layer is disposed between the first substrate and the second substrate, the spacer is used for supporting the first substrate and the second substrate, a positioning structure is disposed between the spacer and the second substrate, the positioning structure includes a groove, one end of the spacer is received in the groove, and the groove is used for positioning the spacer. The present application also provides a method for manufacturing a display panel.

### RELATED APPLICATIONS

This application is a continuation application of PCT Patent Application No. PCT/CN2018/071466, filed Jan. 4, 2018, and claims the priority of China Application CN 201710883544.0, filed Sep. 26, 2017, which is herein incorporated by reference in its entirety.

### FIELD OF THE DISCLOSURE

The present disclosure relates to a display technology field, and more particularly to a display panel and a manufacturing method thereof.

### BACKGROUND OF THE DISCLOSURE

In a large display panel, in order to reduce the deformation of the display panel, a spacer is usually disposed between a color filter substrate and a thin film transistor (TFT) array substrate in a display panel. In order to avoid the dislocation of the spacer, the spacer is usually contacted with the substrate on one side. In this structure, when the liquid crystal panel is collided or deformed, it may cause the spacer to move while the spacer may have poor picture quality due to the position movement.

### SUMMARY OF THE DISCLOSURE

An object of the present application is to provide a display panel and a manufacturing method thereof, in order to improve the display stability of the display panel.

The present application provides a display panel including a first substrate, a liquid crystal layer, a second substrate, and a spacer; the liquid crystal layer is disposed between the first substrate and the second substrate, the spacer is configured to support the first substrate and the second substrate, a positioning structure is disposed between the spacer and the second substrate, the positioning structure includes a groove, one end of the spacer is received in the groove, and the groove is configured to position the spacer.

Wherein an opening of the groove faces the first substrate, a bottom wall of the groove is opposite to the opening, one end of the spacer abuts against the bottom wall, the bottom wall has a protrusion, and one end of the spacer engages with the protrusion.

Wherein the positioning structure is grounded to shield static electricity between the second substrate and the spacer.

Wherein the display panel includes a chip, a grounding end is disposed on the chip, the positioning structure further includes a connecting line, and the connecting line electrically connects the groove and the grounding end.

Wherein the display panel further includes a pixel electrode disposed between the liquid crystal layer and the second substrate; the connecting line, the groove and the pixel electrode are disposed in a same layer, and the connecting line is spaced apart from the pixel electrode.

Wherein the connecting line includes a first connecting line and a second connecting line extending in two different directions and connected to each other, the display panel further includes a data line and a scan line, the first connecting line and the second connecting line respectively cover the data line and the scan line.

Wherein the materials of the connecting line and the positioning structure are the same as the material of the pixel electrode.

Wherein the first substrate is a color filter substrate, and the second substrate is a TFT array substrate.

The present application further provides a manufacturing method of a display panel, including:
providing a first substrate and a second substrate;
forming a positioning structure on the second substrate, the positioning structure including a groove;
forming a spacer on the first substrate or the positioning structure and aligning the first substrate and the second substrate to support the spacer between the first substrate and the second substrate, and receiving one end of the spacer in the groove.

wherein the step of forming a positioning structure on the second substrate includes:
forming a conductive material on the second substrate, applying a photoresist and etching to form spaced-apart positioning structure areas and pixel electrodes;
etching the positioning structure area to form the groove and a connecting line connected with the groove, and the connecting line is configured to ground the groove.

In the display panel provided by the present application, the groove and the connection line are formed by depositing the positioning structure on the TFT array substrate and using a Halftone Mask technology. The groove is used for positioning the spacer that supports the thickness of the liquid crystal cell so as to avoid the poor picture quality caused by the position movement of the spacer in the display panel. Moreover, the groove and the connecting line are grounded. Therefore, the groove and the connecting line can also release the static electricity caused by the relative friction of the supporting rod to avoid the bright spots or the dark spots on the display panel, thereby improving the display quality. The method for manufacturing the display panel provided by the present application requires no increase in the number of times of masking, which makes the manufacture of the display panel simple and convenient.

### BRIEF DESCRIPTION OF THE DRAWINGS

To describe the technical solutions in the embodiments of the present application more clearly, the following briefly introduces the accompanying drawings required for describing the embodiments. Apparently, the accompanying drawings in the following description show merely some embodiments of the present application, and a person of ordinary skill in the art may still derive other drawings from these accompanying drawings without creative efforts.

FIG. 1 is a schematic structural diagram of a display panel according to an embodiment of the present application.

FIG. 2 is a cross-sectional structural diagram of one embodiment of area I in FIG. 1 along an AB direction.

FIG. 3 is a cross-sectional structural diagram of another embodiment of area I in FIG. 1 along the AB direction.

FIG. 4 is a cross-sectional structural diagram of the other embodiment of area I in FIG. 1 along the AB direction.

FIG. 5 is a flowchart of a method for manufacturing a display panel according to an embodiment of the present application.

FIG. 6 is a schematic structural diagram of a display panel corresponding to step S101 in the manufacturing method provided by FIG. 5.

FIG. 7 is a schematic structural diagram of a display panel corresponding to step S101 in the manufacturing method provided by FIG. 5.

FIG. 8 is a schematic structural diagram of a display panel corresponding to step S102 in the manufacturing method provided by FIG. 5.

FIG. 9 is a schematic structural diagram of a display panel corresponding to step S102 in the manufacturing method provided by FIG. 5.

FIG. 10 is a schematic structural diagram of a display panel corresponding to step S102 in the manufacturing method provided by FIG. 5.

FIG. 11 is a schematic structural diagram of a display panel corresponding to step S102 in the manufacturing method provided by FIG. 5.

FIG. 12 is a schematic structural diagram of a display panel corresponding to step S102 in the manufacturing method provided by FIG. 5.

FIG. 13 is a schematic structural diagram of a display panel corresponding to step S102 in the manufacturing method provided by FIG. 5.

### DETAILED DESCRIPTION OF PREFERRED EMBODIMENTS

The technical solutions of the embodiments of the present application are clearly and completely described below with reference to the accompanying drawings in the embodiments of the present application.

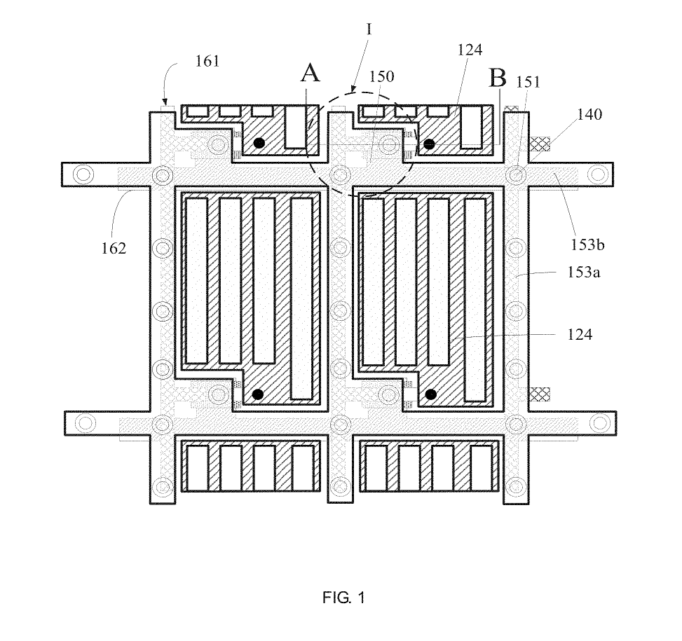

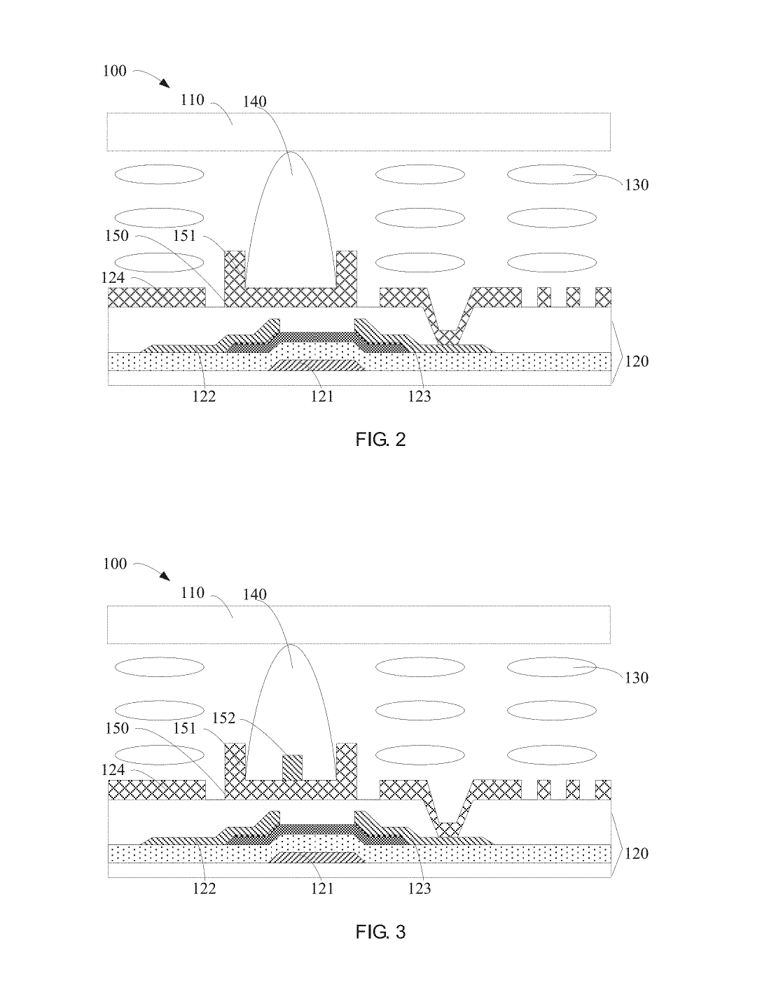

Referring to FIG. 1 and FIG. 2, FIG. 1 is a partial structural diagram of a display panel 100 according to an embodiment of the present application. FIG. 2 is a schematic cross-sectional structure of area I in FIG. 1 along the direction AB, and is a switching TFT area of the TFT array substrate 120. The display panel 100 includes a first substrate 110, a liquid crystal layer 130, a second substrate 120, and a spacer 140. The liquid crystal layer 130 is disposed between the first substrate 110 and the second substrate 120. The spacer 140 is used to support the first substrate 110 and the second substrate 120. A positioning structure 150 is disposed between the spacer 140 and the second substrate 120.

The spacer 140 may be disposed on the first substrate 110 (also a color filter substrate in the present embodiment) or on the second substrate 120 (also a TFT array substrate in the present embodiment). When the spacer 140 is disposed on the TFT array substrate, the array substrate thus formed has a step difference due to different patterns of the layers in the TFT array substrate, resulting in the position of the spacer 140 being shifted. The spacer 140 may move to the display area, so that a bright spot or a dark spot may appear on the display panel 100.

In response to the above problem, the display panel 100 provided by the present application forms the groove 151 by a Halftone Mask technique by depositing a positioning structure 150 on the TFT array substrate. One end of the spacer 140 is received in the groove 151. The groove 151 is used for positioning the spacer 140 so as to prevent the spacer 140 from moving, so as to improve the display quality.

Due to the relative friction between the spacer 140 and the second substrate 120, an electrostatic charge is generated, thereby forming an electric field that charges the charges in the channel of the TFT. While the gate 121 of the TFT is at a low voltage, the source 122 and the drain 123 should be kept disconnected. If sufficient charge is accumulated in the TFT channel, the source 122 and the drain 123 will remain conductive, in addition, the drain 123 continues to supply power to the pixel electrode 124. As a result, the display panel 100 depresses the black screen to form unstable finger-pressure bright spots, resulting in poor display of the display panel 100.

In an implementation manner, referring to FIG. 1 and FIG. 2, the positioning structure 150 is connected to a ground (not shown). The periphery of the display panel 100 is further provided with a chip (not shown), and the ground is provided on the chip. The positioning structure 150 further includes a connecting line 153. The connecting line 153 electrically connects the groove 151 and the ground. In this embodiment, the second substrate 120 may be a thin film transistor (TFT) array substrate. The first substrate 110 may be a color filter substrate.

In the display panel 100 provided by the embodiment of the present application, a positioning structure 150 is disposed between the spacer 140 and the second substrate 120, and the positioning structure 150 is grounded. So that no relative friction occurs between the positioning structure 150 and the second substrate 120, even though there is relative friction between the spacer 140 and the positioning structure 150, the static charge generated thereby will also enter the grounding end through the positioning structure 150 without affecting the TFT, therefore, the display panel 100 provided in this embodiment can prevent the TFT from being electrostatically disturbed and thereby provide display stability of the display panel 100.

The present application is not limited to the shape of the groove 151. The groove 151 may be circular, square, oval, polygonal or the like, and is actually determined according to the shape of the spacer 140.

Further, referring to FIG. 3, an opening of the groove 151 faces the first substrate 110, and a bottom wall of the groove 151 is opposite to the opening. One end of the spacer 140 abuts against the bottom wall. The bottom wall has a protrusion 152, one end of the spacer 140 has a receiving cavity, the protrusion 152 is engaged in the receiving cavity to further fix the spacer 140 and the groove 151, even when the display panel 100 is in a collision or the like, the spacer 140 and the groove 151 do not move relative to each other, so as to further improve the display yield of the display panel 100 under harsh environments.

Optionally, the material of the positioning structure 150 is a transparent conductive material. The transparent conductive material may be a carbon nanotube, a graphene, a conductive polymer material, a nano-silver wire, a metal mesh or an oxide transparent conductive film, wherein the oxide transparent conductive film may be an indium tin oxide (ITO) transparent conductive film.

Specifically, referring to FIG. 1, the display panel 100 further includes a plurality of data lines 161 and a plurality of scan lines 162. The data line 161 intersects with the extending direction of the scan line 162 to form a plurality of pixel areas, and the pixel area has the pixel electrode 124. The pixel electrode 124 is disposed between the liquid crystal layer 130 and the second substrate 120. The connection line 153, the groove 151 and the pixel electrode 124 are disposed on the same layer, and the connection line 153 is spaced apart from the pixel electrode 121.

The positioning structure 150 can be made of the same material as the pixel electrode 124, and each is an ITO transparent conductive film. The positioning structure 150 can also be made in the same process as the pixel electrode 124.

Specifically, the connecting line 153 includes a first connecting line 153a and a second connecting line 153b extending in different directions and connected to each other. The two directions are the extension directions of the data line 161 and the scan line 162, that is, the first connecting line 153a and the second connecting line 153b respectively cover the data line 161 and the scan line 162. The reason for this design is that since the spacer 140 is to support the entire liquid crystal cell thickness, it is necessary to provide the spacers 140 in each area of the liquid crystal layer 130. In this case, the number of the spacers 140 to be provided is large, and accordingly, the area where the positioning structure 150 is disposed may be correspondingly larger, since the positioning structure 150 is configured to be grounded, it needs to be insulated from the pixel electrode 124. Therefore, the positioning structure 150 can only be disposed in a area between the pixel electrodes 124, the area between the pixel electrodes 124 is just a trace area of the data line 161 and the scan line 162. Therefore, the positioning structure 150 can be disposed directly opposite to the scan line 162.

Optionally, the groove 151 is located on the connecting line 153. The specific position and the number of the groove 151 may be determined according to the position of the spacer 140. The position of the groove 151 in FIG. 1 is a preferred embodiment.

The present application does not limit the shape and size of the positioning structure 150 as long as the positioning structure 150 is insulated from the pixel electrode 124. FIG. 1 is a preferred embodiment of the present proposal.

Optionally, the spacer 140 is formed on the first substrate 110 or the positioning structure 150.

In an implementation manner, referring to FIG. 2, the spacer 140 is formed in the groove 151 on the side of the TFT array substrate 120. The groove 151 can release the static electricity caused by friction of the spacer 140 in time through the first connecting line 153a and the second connecting line 153b, at the same time, the groove 151 can fix the spacer 140, prevent the spacer 140 from moving in position, resulting in a poor picture quality of the display panel 100.

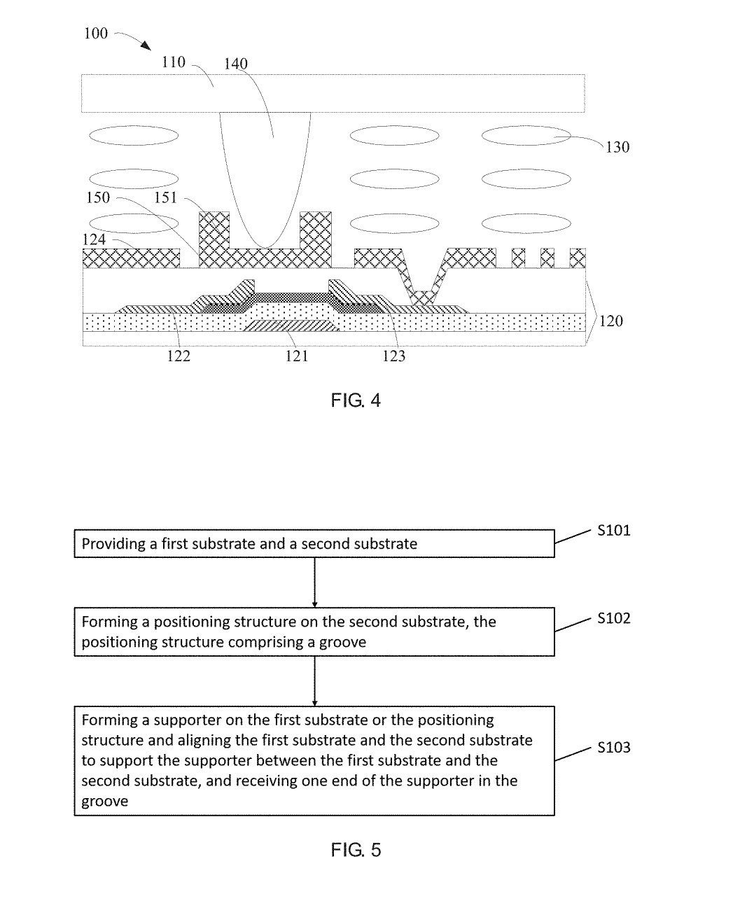

In another implementation manner, referring to FIG. 4, the spacer 140 is fabricated on the side of the color filter substrate 110, and one end of the spacer 140 is in contact with the groove 151 after the mating process, the groove 151 can also fix the spacer 140, prevent the spacer 140 from moving in position, resulting in poor picture quality of the display panel 100, at the same time, the groove 151 can release the static electricity generated by the spacer 140 due to the rubbing of the ITO through the first connecting line 153a and the second connecting line 153b in time.

Referring to FIG. 5, an embodiment of the present application further provides a method for manufacturing the display panel 100. The following steps S101 to S104 are included.

S101. Providing a first substrate 110 and a second substrate 120. The first substrate 110 may be a color filter substrate, and the second substrate 120 may be a TFT array substrate.

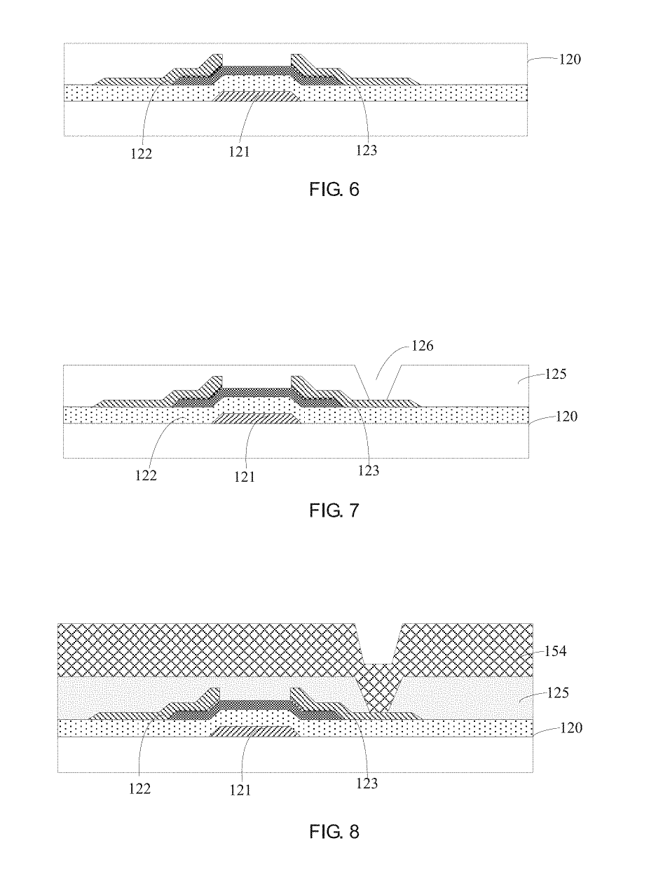

Specifically, referring to FIG. 6 and FIG. 7, the TFT array substrate 120 that has completed the source 122 and the drain 123 is selected and cleaned. An insulating material is deposited on the TFT array substrate 120 to form a flat layer 125. The insulating material may be silicon nitride. Then a planarization process is applied so that the upper surface of the flat layer 125 is planar. Through the photolithography and etching processes, the through hole 126 of the flat layer 125 is formed, the through hole 126 extends to the drain 123, the through hole 126 is used for electrically connecting the subsequent pixel electrode 124 and the drain 123.

S102. Forming a positioning structure 150 on the second substrate 120, and the positioning structure 150 includes a groove 151. The positioning structure 150 is grounded.

Specifically, referring to FIG. 8, since the positioning structure 150 can be fabricated in the same process as the pixel electrode 124, a layer of indium tin oxide (ITO) pixel layer 154 can be sputter-grown on the upper surface of the flat layer 125. The ITO pixel layer 154 is used for forming the positioning structure 150 and the pixel electrode 124.

S102 includes the following steps.

S201. Forming a conductive material on the second substrate 120, applying a photoresist and etching to form a spaced-apart positioning structure area and a pixel electrode 124.

S202. Coating a photoresist layer 160 on the positioning structure 150 and performing exposure and development so that the photoresist layer 160 forms a photoresist half-reserved area 161 and a photoresist fully-reserved area 162.

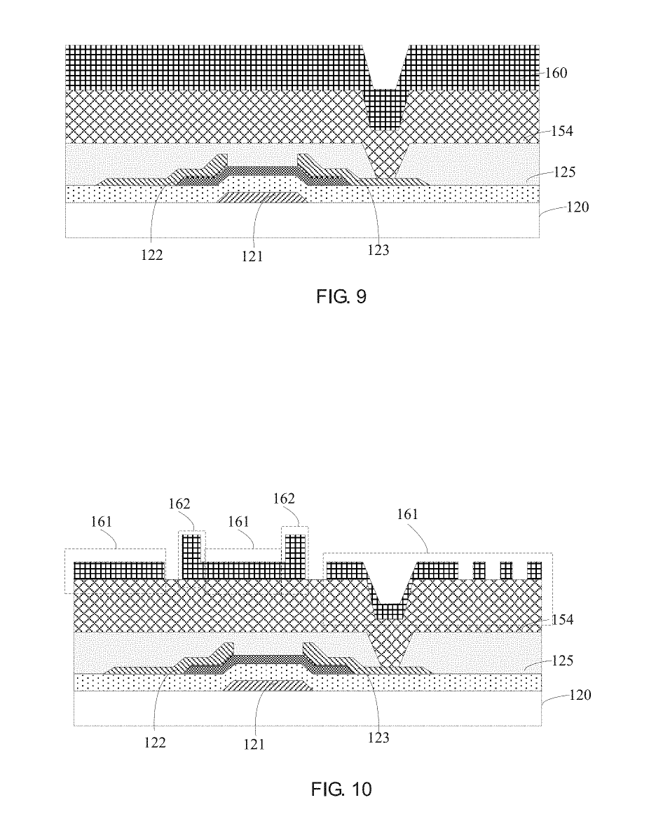

Specifically, referring to FIG. 9 and FIG. 10, a photoresist layer 160 is coated on the upper surface of the ITO pixel layer 154. The photoresist layer 160 is exposed and developed. After development, the photoresist layer 160 is divided into two parts, a photoresist half-reserved area 161 and a photoresist fully-reserved area 162.

S203. First etching the positioning structure 150 to form a groove area 155 and a connecting line 153. The connecting line 153 includes a first connecting line 153a and a second connecting line 153b connected to each other.

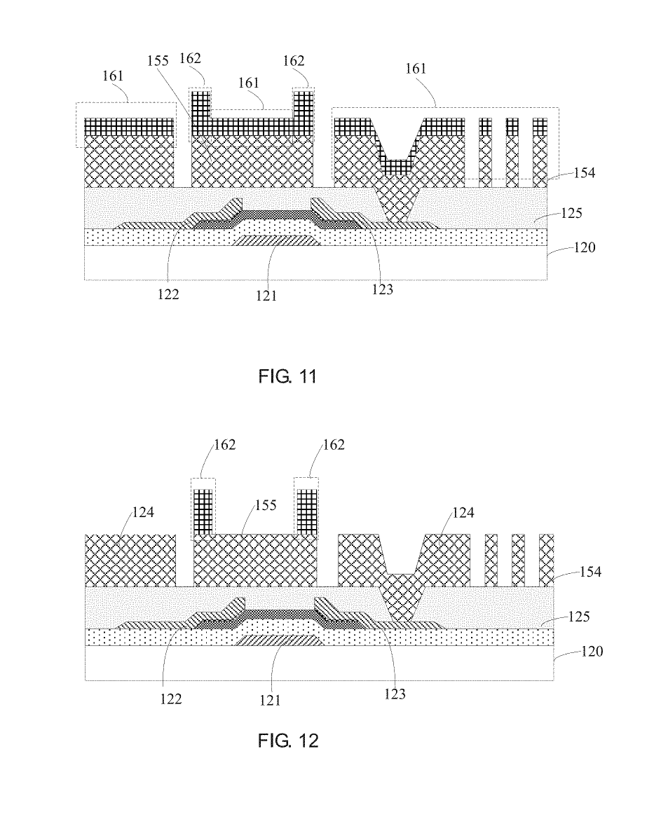

Specifically, referring to FIG. 11 and FIG. 12, the ITO pixel layer 154 is etched by the oxalic acid solution, and the area not protected by the photoresist layer 160 is completely etched away. The ITO pixel layer 154 is divided into two parts: the pixel electrode 124 and the groove area 155, and the two are completely disconnected.

Through the photoresist ashing process, the photoresist layer 160 is ashed, the photoresist half-reserved area 161 is completely etched away, and the photoresist layer 160 only has the photoresist-fully-reserved area 162.

S204. Second etching the groove area 155 and the connecting line 153 to form the groove 151 and thin the connecting line 153, the connecting line 153 is electrically connected to the groove 151 and the ground on the chip.

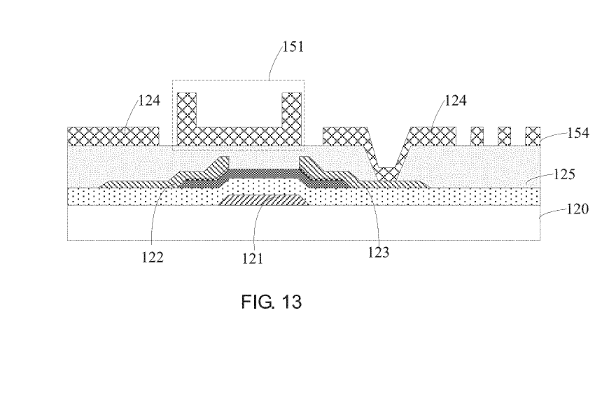

Specifically, referring to FIG. 13, the oxalic acid solution is continuously used to etch the entire pixel electrode 124 and the groove 151 of the photoresist with the photoresist-fully-reserved area 162 as an etching-resistant layer. After etching a certain thickness, the etching is stopped. At this time, the pixel electrode 124 is thinned, and the two sides of the groove area 155 are protected by the photoresist fully-retained area 162, thereby forming the groove 151 completely disconnected from the pixel electrodes 124 on both sides.

S103. Referring to FIG. 1, forming a spacer 140 on the first substrate 110 or the positioning structure 150, aligning the first substrate 110 and the second substrate 120, such that the spacer 140 is supported between the first substrate 110 and the second substrate 120, and one end of the spacer 140 is received in the groove 151. The positioning structure 150 is connected to the spacer 140 to shield the static electricity between the second substrate 120 and the spacer 140.

According to the manufacturing method of the display panel 100 provided in this embodiment, the pixel electrode 124 and the groove 151 are simultaneously etched to be completed.

The present application proposes a display panel 100. An ITO material groove 151 and a connecting line 153 are formed by depositing an ITO transparent positioning structure on the TFT array substrate 120 and using a Halftone Mask technology. The groove 151 is used for positioning the spacer 140 for supporting the thickness of the liquid crystal cell, so as to avoid the poor picture quality caused by the position movement of the spacer 140 in the display panel 100. Moreover, the connecting line 153 is electrically connected to the ground. The groove 151 and the connecting line 153 also release static electricity generated by the relative friction of the spacer 140 to prevent the bright or dark spots of the display panel 100 from occurring and improve the display quality. According to the manufacturing method of the display panel 100 provided by the present application, the number of times of masks does not need to be increased, so that the manufacturing of the display panel 100 is simple and convenient.

The above is the preferred embodiment of the present application, it should be noted that those skilled in the art may make various improvements and modifications without departing from the principle of the present application, and these improvements and modifications are also deemed to be within the protection scope of the present application.

What is claimed is:

1. A display panel, comprising a first substrate, a liquid crystal layer, a second substrate, and a spacer; wherein the liquid crystal layer is disposed between the first substrate and the second substrate, the spacer is configured to support the first substrate and the second substrate, a positioning structure is disposed between the spacer and the second substrate, the positioning structure has a groove, one end of the spacer is received in the groove, and the groove is configured to position the spacer.

2. The display panel according to claim 1, wherein an opening of the groove faces the first substrate, a bottom wall of the groove is opposite to the opening, one end of the spacer abuts against the bottom wall, the bottom wall has a protrusion, and one end of the spacer engages with the protrusion.

3. The display panel according to claim 1, wherein the positioning structure is grounded to shield a static electricity between the second substrate and the spacer.

4. The display panel according to claim 2, wherein the positioning structure is grounded to shield a static electricity between the second substrate and the spacer.

5. The display panel according to claim 4, wherein the display panel comprises a chip, a grounding end is disposed on the chip, the positioning structure further comprises a connecting line, and the connecting line electrically connects the groove and the grounding end.

6. The display panel according to claim 5, wherein the display panel further comprises a pixel electrode disposed between the liquid crystal layer and the second substrate; the connecting line, the groove and the pixel electrode are disposed in a same layer, and the connecting line is spaced apart from the pixel electrode.

7. The display panel according to claim 6, wherein the connecting line comprises a first connecting line and a second connecting line extending in two different directions and connected to each other, the display panel further comprises a data line and a scan line, the first connecting line and the second connecting line cover the data line and the scan line, respectively.

8. The display panel according to claim 7, wherein materials of the connecting line and the positioning structure are the same as a material of the pixel electrode.

9. The display panel according to claim 1, wherein the first substrate is a color filter substrate, and the second substrate is a TFT array substrate.

10. A method for manufacturing a display panel, comprising:
providing a first substrate and a second substrate;
forming a positioning structure on the second substrate, the positioning structure comprising a groove;
forming a spacer on the first substrate or the positioning structure, and aligning the first substrate and the second substrate to support the spacer between the first substrate and the second substrate, and receiving one end of the spacer in the groove.

11. The method for manufacturing a display panel according to claim 10, wherein the step of forming a positioning structure on the second substrate comprises:
forming a conductive material on the second substrate, coating a photoresist and etching it to form spaced-apart positioning structure areas and pixel electrodes;
etching the positioning structure area to form the groove and a connecting line connected with the groove, and the connecting line is configured to ground the groove.
